(19) United States
(12) Patent Application Publication
(10) Pub. No.: US 2026/0360674 A1
(43) Pub. Date: Nov. 12, 2026

(54) ENHANCED CARBON FILM EDGE THICKNESS PROFILE TUNABILITY BY FOCUS RING

(71) Applicant: Lam Research Corporation, Fremont, CA (US)

(72) Inventors: Huifeng Zheng, Beaverton, OR (US); Hu Kang, Vancouver, WA (US); Dong Wang, Sherwood, OR (US); Yuhui Li, Wilsonville, OR (US); Joseph Lindsey Womack, Tigard, OR (US); Ming Li, West Linn, OR (US)

(21) Appl. No.: 19/491,611

(22) PCT Filed: Jun. 14, 2024
(86) PCT No.: PCT/US2024/034089

§ 371 Date: Dec. 9, 2025

Related U.S. Application Data
(60) Provisional application No. 63/508,815, filed on Jun. 16, 2023.

(51) Int. Cl. H01J 37/32; C23C 16/455; C23C 16/458; H10P 14/60

(52) U.S. Cl. CPC H01J 37/32642; C23C 16/4581; C23C 16/4585; H10P 14/6336; C23C 16/45536; C23C 16/45565; H01J 2237/3321; H01J 2237/3323

(57) ABSTRACT

Methods and apparatuses for controlling uniformity of processing at an edge region of a semiconductor wafer are disclosed. In some embodiments, the methods include depositing carbon-containing films. Also provided herein are focus rings including that may be implemented to provide control of the processing environment at the edge of the wafer.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

A challenge in semiconductor processing is achieving film uniformity across as large an expanse of a processed wafer as possible. Managing the semiconductor processing environment at the edge regions of a semiconductor wafer presents challenges. In particular, the discontinuities at the edge regions can make uniform processing difficult.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are methods and systems for depositing films using a focus ring. In one aspect of the embodiments herein, a system is provided, the system including: a process chamber including a pedestal including a top surface; a focus ring installed on the top surface of the pedestal, wherein the focus ring includes an annular ring having an inner diameter and an outer diameter; and a controller configured to execute machine-readable instructions to control the process chamber for: depositing a carbon-containing film using a plasma-enhanced deposition process on a wafer. In some embodiments, the focus ring includes a dielectric material. In some embodiments, the dielectric material is aluminum oxide. In some embodiments, the inner diameter of the focus ring is between about 11.9 inches and about 13 inches. In some embodiments, the outer diameter of the focus ring is at least about 14 inches. In some embodiments, the focus ring includes posts that contact the top surface of the pedestal. In some embodiments, a gap between the annular ring and the top surface of the pedestal is at least about 0.01 inches. In some embodiments, a distance between the top surface of the pedestal and a top surface of the focus ring when the focus ring is installed on the top surface of the pedestal is between about 0.06 and about 0.182 inches. In some embodiments, the process chamber further includes a showerhead, and a distance between the showerhead and the top surface of the pedestal is between about 0.5 inches and about 1.5 inches. In some embodiments, depositing the carbon-containing film is performed at a temperature between about 200 °C and about 650 °C. In some embodiments, depositing the carbon-containing film is performed at a temperature between about 250 °C and about 550 °C. In some embodiments, depositing the carbon-containing film is performed at a temperature less than about 550 °C. In some embodiments, depositing the carbon-containing film is performed at a low-frequency power between about 1000 W and about 1500 W per 300 mm wafer. In some embodiments, depositing the carbon-containing film is performed at a high-frequency power between about 100 W and about 250 W per 300 mm wafer. In some embodiments, a non-uniformity of the carbon-containing film at a radius greater than about 130 mm is less than about 10%.

In another aspect of the embodiments herein, a method is provided, the method, including: receiving a wafer in a process chamber including a pedestal including a top surface, wherein a focus ring is installed on the top surface of the pedestal, wherein the focus ring includes an annular ring having an inner diameter and an outer diameter; and depositing a carbon-containing film using a plasma-enhanced deposition process on the wafer. In some embodiments, the focus ring includes a dielectric material. In some embodiments, the dielectric material is aluminum oxide. In some embodiments, the inner diameter of the focus ring is between about 11.9 inches and about 13 inches. In some embodiments, the outer diameter of the focus ring is about 14.75 inches. In some embodiments, the focus ring includes posts that contact the top surface of the pedestal. In some embodiments, a gap between the annular ring and the top surface of the pedestal is about 0.02 inches. In some embodiments, a distance between the top surface of the pedestal and a top surface of the focus ring when the focus ring is installed on the top surface of the pedestal is between about 0.06 and about 0.182 inches. In some embodiments, the process chamber further includes a showerhead, and a distance between the showerhead and the top surface of the pedestal is between about 0.5 inches and about 4 inches. In some embodiments, depositing the carbon-containing film is performed at a temperature between about 200 °C and about 650 °C. In some embodiments, depositing the carbon-containing film is performed at a temperature between about 250 °C and about 550 °C. In some embodiments, depositing the carbon-containing film is performed at a temperature less than about 550 °C. In some embodiments, depositing the carbon-containing film is performed at a low-frequency power between about 1000 W and about 1500 W per 300 mm wafer. In some embodiments, depositing the carbon-containing film is performed at a high-frequency power between about 100 W and about 250 W per 300 mm wafer. In some embodiments, a non-uniformity of the carbon-containing film at a radius greater than about 130 mm is less than about 10%.

These and other features of the disclosed embodiments will be described in detail below with reference to the associated drawings.

### BRIEF DESCRIPTION OF DRAWINGS

FIG. 1A depicts an isometric view of an example of an focus ring installed on a wafer support that may be used in implementations of the disclosure.

FIG. 1B shows an exploded isometric view of an example of an focus ring, wafer, and wafer support that may be used in implementations of the disclosure.

FIGS. 1C and 1D show top and bottom views, respectively, of an example of a focus ring that may be used in implementations of the disclosure.

FIG. 1E shows a side view of a focus ring that may be used in implementations of the disclosure.

FIG. 2 presents an illustration of a side cut-out view of a chamber having a focus ring in various implementations of the disclosure.

FIG. 3 presents a flowchart of operations to deposit films according to various aspects of the present disclosure.

FIG. 4 presents a table of data for radial non-uniformity of films deposited using various focus rings according to the disclosure herein.

FIGS. 5-8 are schematic diagrams of examples of process chambers for performing methods in accordance with disclosed embodiments herein.

### DETAILED DESCRIPTION

A frequent driver in semiconductor processing is achieving process uniformity across as large an expanse of a processed wafer as possible. Edge regions of wafers present particular difficulties due to the discontinuities they represent. Managing the behavior of the semiconductor processing environment in the edge region of the semiconductor wafer may present particular challenges. This challenge is particularly present in plasma-based fabrication operations, where a plasma is formed above a wafer to be processed. It is desirable to control the properties of the plasma, particularly near the edge region of wafers, however there are limited options for such control. Edge region non-uniformity presents a challenge for processing control without also impacting non-edge regions of the wafer.

In particular, during plasma-based carbon mask deposition operations it is desirable to have minimal radial non-uniformity, particularly at edge regions of the wafer, e.g., regions of the wafer at a radius greater than about 130 mm or about 140 mm (e.g., for a 300 mm diameter wafer; other size wafers the edge region may be scaled appropriately). However, in some plasma-based carbon mask deposition operations there is insufficient or excessive deposition at the edge of the wafer and it is difficult to appropriately tune the deposition. This edge non-uniformity may result from plasma non-uniformity in the space above the wafer edge. The density of the plasma may change near the wafer edge, which results in changing deposition of a carbon mask on the wafer.

One method of tuning edge deposition is controlling a process chamber pressure or the gap between a pedestal and a showerhead will affect deposition, however changing these parameters do not only affect the wafer edge regions and also affect non-edge regions as well, which is undesirable. Alternatively, an etch back process (e.g., an oxygen-based etch process for a carbon hardmask) may be performed to remove excess deposition at edge regions, however this decreases throughput and introduces additional non-uniformity from the etch back process.

A focus ring may be used to control the plasma deposition at wafer edge regions without substantially affecting non-edge regions of the wafer. A focus ring may be installed on a wafer support, such as a pedestal, and may affect the plasma near the wafer edge regions to reduce non-uniformity without significantly affecting non-edge regions. In some embodiments the focus ring may be an annular ring comprising a ceramic and having an inner diameter and an outer diameter. Materials suitable for a focus ring include ceramic materials such as silicon oxide (e.g., quartz) or aluminum oxide (e.g., Al₂O₃).

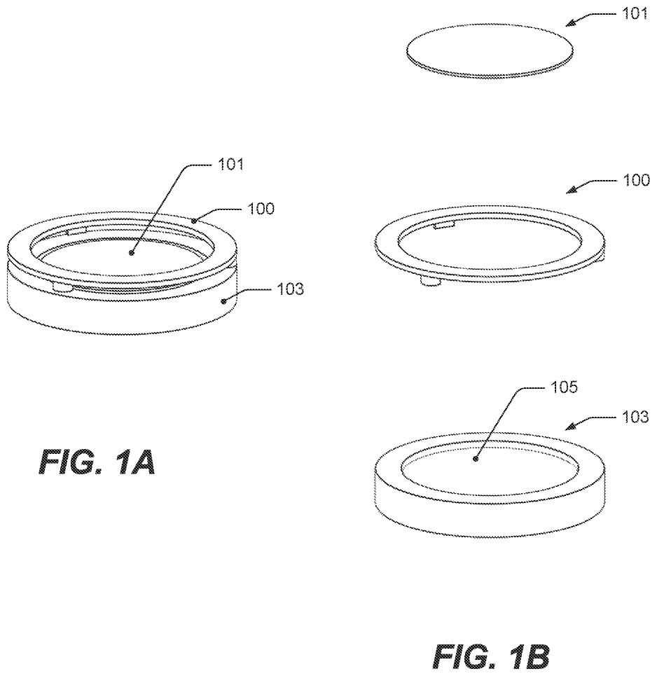

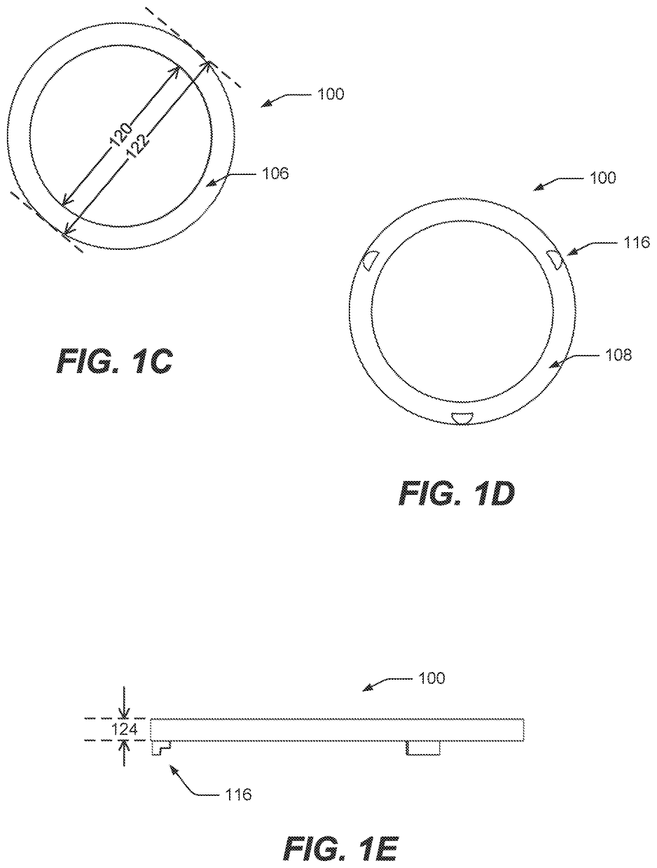

Examples of a focus ring that may be used in various embodiments herein is described in reference to FIGS. 1A-E. FIG. 1A presents an isometric view of a focus ring installed on a wafer support. A focus ring 100 may be used to manage gas flows and process environments along the edge of a substrate or wafer 101, which may be supported by a wafer support 103. FIG. 1B shows an exploded isometric view of the focus ring 100, wafer 101, and wafer support 103 along with a recess 105 in wafer support 103 in which wafer 101 may be positioned during processing.

FIGS. 1C and 1D show bottom and side views, respectively, of a focus ring. The focus ring 100 may be broadly described as a thin, annular ring with an inner diameter 120 and an outer diameter 122. The focus ring 100 may, in some implementations, include a plurality of posts 116 that project from a bottom surface 108 of the focus ring 100. A top surface 106 and bottom surface 108, which may also be referred to herein as first and second surfaces, respectively, of the focus ring 100 may be substantially parallel to a reference plane that is perpendicular to the center axis of the annular ring. It is to be recognized that the terms “top” and “bottom,” with respect to focus rings, are relative terms that, in the context of this application, refer to the surfaces of the focus rings that appear to be “top” and “bottom” when the focus rings are in use in a semiconductor processing environment rather than an arbitrary top and bottom defined by the orientation of the focus rings at any given instant. Moreover, there may be portions of the top surface 106 and the bottom surface 108 that are not parallel to the reference plane. For example, the posts 116 project from the bottom surface 108 of the focus ring 100. The inner diameter 122 of the focus ring 100 may be larger than the nominal diameter of the semiconductor wafer such there is a radial gap between the semiconductor wafer and the focus ring 100 when in use in the methods described herein. As a whole, however, the top surface 106 and the bottom surface 108 may be substantially parallel to the reference plane-such that most of radial distances of the surfaces are parallel to the reference plane. The top surface 106 and the bottom surface 108 may be offset from each other by a thickness 124 that defines a thickness of the focus ring 100, as shown in FIG. 1E.

In various embodiments, outer diameter 122 may be at least about 14 inches, between about 14 inches and 15 inches, or about 14.75 inches. In various embodiments, the inner diameter 120 may be between about 11.9 inches and about 13 inches, between about 11.9 inches and about 12.1 inches, between about 12 and 13 inches, greater than about 11.9 inches, or less than about 13 inches. As discussed further herein, the inner diameter of a focus ring may be based upon processing parameters for a carbon-containing film deposition. The inner diameter and/or thickness of a focus ring may affect edge deposition such that the inner diameter and/or thickness may be selected to reduce radial edge non-uniformity. In some embodiments, the thickness of a focus ring may be between about 0.06 and about 0.182 inches.

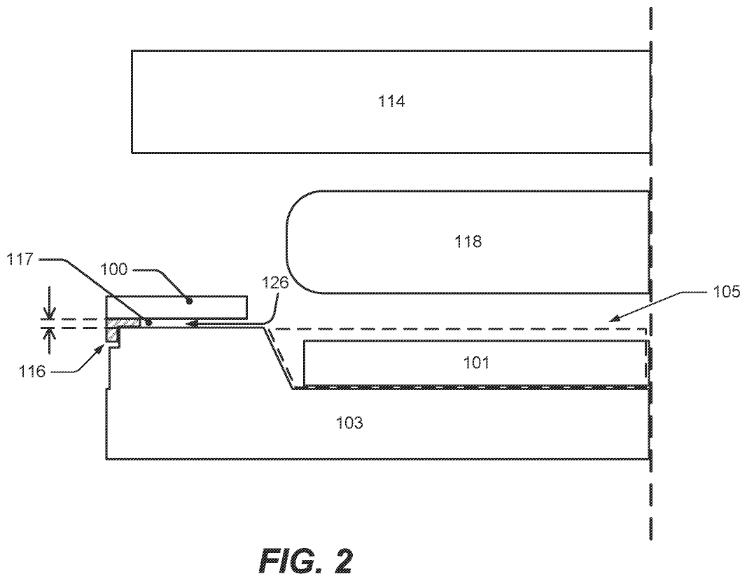

In deposition of films such as carbon-containing films, a focus ring can be used to modulate deposition at the wafer edge. FIG. 2 shows a schematic illustration of a pedestal (or other wafer support) including a focus ring such as the focus ring shown in FIG. 1A-E. A wafer support 103 may comprise a recess 105 in which a wafer may be positioned, as well as a focus ring 100 placed on the wafer support 103. The wafer and the focus ring may be concentric. In some embodiments, the posts 116 may contact the wafer support 103 and elevate the bottom surface of the focus ring relative to the wafer support, forming a gap 117 when the focus ring is placed upon the wafer support. The gap 117 may facilitate a gas flow path 126 that allows gases to flow under the focus ring 100 away from the wafer 101. In various embodiments the gap 117 may have a minimum distance between the bottom surface of the focus ring and the top surface of the pedestal of between about 0.01 and about 0.05 inches, between about 0.01 and about 0.03 inches, at least about 0.01 inches, at least about 0.02 inches, or about 0.02 inches. The inner edge of focus ring 100 may have various shapes, including chamfers, rounding to various radii, squared, etc.

A showerhead 114 may be positioned above the wafer support 103. In some embodiments, a showerhead gap 115 between the wafer support 103 and the showerhead 114 is greater than about 0.5 inches (about 12 mm), greater than about 1 inch (about 25 mm), between about 0.5 and about 1.5 inches (about 38 mm), or between about 0.5 inches (about 12 mm) and about 4 inches (about 100 mm).

In some embodiments, a focus ring may be used to improve radial non-uniformity of a carbon-containing film deposition process. In some embodiments, the carbon-containing film deposition process may be performed at a low temperature, low pressure, and wide gap between the pedestal and the showerhead. Carbon-containing films deposited under such conditions may have improved density and etch selectivity, particularly for high aspect ratio etching associated with 3D NAND devices. However, in some embodiments, process conditions for depositing such films also increase radial non-uniformity during deposition of the carbon-containing films. During deposition a plasma 118 may form above the pedestal and substrate, from which ions of gases may form and flow towards the substrate to deposit a carbon-containing film. A focus ring as described herein may affect the edge of the plasma 118 near the radial edge of substrate 101 to improve radial uniformity.

A focus ring may confine a plasma density at the edge of the pedestal and therefore control a deposition rate at the edge of wafer. By adding in a dielectric focus ring as described herein, an edge profile may be further controlled without affecting non-edge deposition. Unlike profile tuning or etch back, a focus ring improves low-temperature AHM edge profiles without reducing throughput or adjusting other process parameters, and may even improve throughput. A focus ring may thus improve non-uniformity at the edge of the wafer, e.g., the region at a radial distance greater than about 130 mm or greater than about 140 mm for a 150 mm wafer. Suitable adjustments to the radial distance for an edge region may be made for larger or smaller diameter wafers. Notably, a focus ring may improve edge deposition uniformity without affecting deposition at the non-edge portion of the wafer or the film's material properties, e.g., etch selectivity.

### Process Window

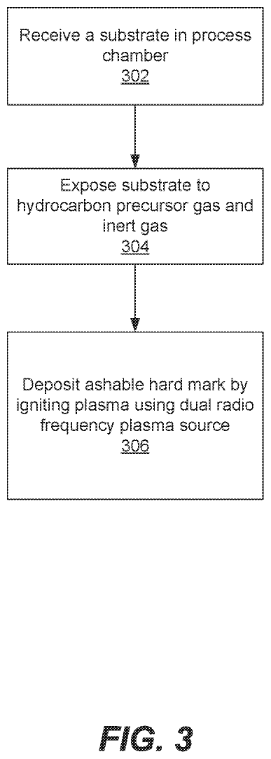

FIG. 3 shows a process flow diagram showing relevant operations of methods of forming ashable hard masks (AHM) or carbon-containing films by dual RF plasma power according to various embodiments. In operation 302 a substrate is received in a process chamber. The substrate may be provided to the chamber in this operation, or the substrate may already be in the chamber from a prior operation. In operation 304 the substrate is exposed to a process gas including a hydrocarbon precursor. In addition to hydrocarbon precursors, an inert gas carrier may be used. The inert gas may include helium (He), argon (Ar), nitrogen (N₂), or a combination of any of these.

Next, in operation 306, an ashable hard mask is deposited on the substrate by a PECVD process by igniting plasma using a dual RF plasma source to produce a plasma having a low frequency (LF) component and a high frequency (HF) component. The result of operation 306 is an ashable hard mask (AHM) film.

Various process parameters that may be employed to produce AHM films. The process parameters are provided for a plasma enhanced chemical vapor deposition process that takes place in a process chamber such as one described herein.

In various embodiments, the total pressure in the process chamber is between about 0.5 Torr and about 20 Torr. In some embodiments, pressure is between about 5 Torr and about 10 Torr, between about 0.5 Torr and about 1.5 Torr, between about 0.5 Torr and about 10 Torr, between about 0.5 Torr and about 5 Torr, or between about 0.5 Torr and about 2.5 Torr. In some embodiments, a hydrocarbon precursor is present in the process chamber at a relatively low partial pressure, e.g., between about 0.01 Torr and about 4 Torr, as discussed in U.S. Pat. Nos. 7,981,777 and 7,981,810, which are incorporated by reference herein in their entireties. In certain embodiments, the hydrocarbon precursor partial pressure is at or below about 0.2 Torr.

In some embodiments, the hydrocarbon precursor is one defined by the formula CₓH_{y}, wherein X is an integer between 2 and 10, and Y is an integer between 2 and 24. Examples include methane (CH₄), acetylene (C₂H₂), ethylene (C₂H₄), propylene (C₃H₆), butane (C₄H₁₀), cyclohexane (C₆H₁₂), benzene (C₆H₆), and toluene (C₇H₈). In certain embodiments the hydrocarbon precursor is a halogenated hydrocarbon, where one or more hydrogen atoms are replaced by a halogen, particularly fluorine, chlorine, bromine, and/or iodine. In some embodiments the hydrocarbon precursor comprises compounds having a molecular weight of at most about 50 g/mol. In some embodiments the hydrocarbon precursor has a ratio of C:H of at least 1:2. In some embodiments the hydrocarbon precursor is acetylene (C₂H₂). In some embodiments, two or more hydrocarbon precursors may be used.

In some embodiments the inert gas comprises at least about 50% or at least about 80% or at least about 95% helium by volume of all inert gas used. In some embodiments the inert gas is helium substantially without any other inert gas.

Precursor gas volumetric flow rates depend on the particular process chamber, substrate, and other process conditions. Examples of volumetric flow rates that may be used for a single 300 mm substrates are between about 10 sccm and about 1,000 sccm of acetylene and between about 250 sccm and about 5,000 sccm of helium. In some embodiments the flow rate of acetylene is between about 1% and about 3% of the total flow rate and helium comprises the rest of the total flow rate. In some embodiments the volumetric flow is between about 15 sccm and about 45 sccm C₂H2, and between about 1455 sccm and about 1485 sccm helium. In some embodiments the volumetric flow is between about 18 sccm and about 20 sccm C₂H₂, and between about 1480 sccm and about 1482 sccm helium, all values per 300 mm substrate. In some embodiments the volumetric flow rate is between about 40 sccm and about 45 sccm C₂ H2, and between about 1455 sccm and about 1460 sccm helium. Unless otherwise specified, the flow rates disclosed herein are for a single station tool configured for 300 mm wafers. Flow rates generally scale linearly with the number of stations and substrate area.

The AHM film deposition methods described herein may be performed at any appropriate process temperature to obtain desired AHM characteristics, with examples ranging from about 50 °C to about 650 °C. In some embodiments the process temperature is between about 200 °C and about 650 °C, between about 250 °C and about 650 °C, or between about 250 °C and about 550 °C. In some embodiments, a process temperature is a low temperature, which may be a temperature less than about 400 °C.

In some embodiments, low frequency (LF) RF power refers to an RF power having a frequency between about 100 kHz and about 2 MHz. In some embodiments, pulsing frequency may be limited by the operation capability of the LF generator. In some embodiments, LF RF power has an RF power with a frequency of about 400 kHz, for example 430 kHz. High frequency RF power refers to an RF power having a frequency between about 2 MHz and about 60 MHz. In some embodiments, HF RF power has an RF power with a frequency of about 13.56 MHz.

In some embodiments, a combination of LF power and HF power is used. In some embodiments, the LF power is at least 1000 W per 300 mm substrate. In some embodiments the LF on power is between about 1000 W and about 1200 W per 300 mm substrate. In various embodiments, the LF power may be pulsed between a minimum and maximum LF power. In some embodiments, the HF power per substrate is between about 0 W and about 250 W per 300 mm substrate. In some embodiments, the HF power per substrate is between about OW and about 1000 W. In many embodiments, the minimum power of the HF RF component and the minimum power of the LF RF component are sufficient to maintain a plasma. All powers provided herein are per 300 mm substrate. RF power as described herein generally scales linearly with number of stations and area of wafers. The power values may be represented on a per area basis, e.g., 2500 W may also be represented as 0.884W/cm².

### EXAMPLES

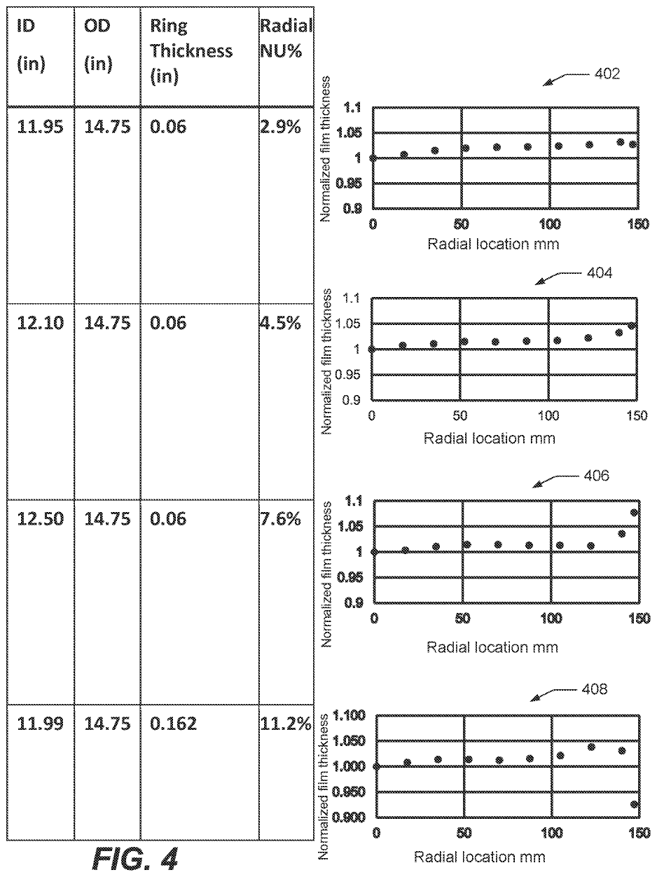

FIG. 4 presents a chart of focus ring dimensions and associated radial non-uniformity charts 402-408. ID and OD refer to inner diameter and outer diameter, respectively, and ID, OD, and thickness are measured in inches. Inner diameter and thickness were varied between focus rings and a carbon-containing film was deposited using each focus ring. The thickness of the focus ring is based on the thickness of the annular portion of the ring; each focus ring shown in FIG. 4 also includes a 0.02 inch gap between the focus ring and the pedestal from focus ring posts that elevate the focus ring above the pedestal.

When the thickness of the focus ring is 0.08 inches and the inner diameter is varied, the radial edge deposition thickness may change from less than average deposition to greater than average deposition, as shown by normalized film thickness in charts 403, 404, and 406. Generally, increase the inner diameter may result in greater edge deposition. Similarly, when the thickness of the focus ring is increased, film deposition at the edge may decrease, as shown in chart 408. Varying the inner diameter and thickness of a focus ring may change the radial deposition profile, which may be selected based on other deposition parameters. For example, temperature and pressure may also affect the radial edge deposition profile, and a focus ring may be tuned to have a particular inner diameter and thickness to improve radial non-uniformity according to the embodiments disclosed herein. The measurements shown in FIG. 4 are based upon specific process parameters, e.g., gas flows and RF power, and varying such process parameters while using the same focus ring may result in different film deposition near the radial edge of wafers. Notably, however, the use of a focus ring may allow for tuning deposition near the wafer edge while substantially not affecting deposition in non-edge regions.

### Applications

AHMs are typically used for creating features of semiconductor devices by etching one or more underlying layers of a substrate. Materials that may be etched using an AHM may include silicon (single crystal, polysilicon, or amorphous silicon), silicon oxide, silicon nitride, and tungsten. In some embodiments multiple layers are stacked and etched using a single AHM. Examples of such stacks include a layer of silicon and a layer of silicon oxide, and a layer of tungsten and a layer of silicon nitride. In some embodiments a stack includes repeating layers that are etched using a single AHM. Examples of such repeating layers include repeating layers of silicon oxide/polysilicon (OPOP). Front end of line and back end of line features may be etched using an AHM as disclosed herein. Memory or logic device features may be patterned. Examples of memory devices include: DRAM, NAND, and 3D NAND.

### Apparatus

Embodiments can be implemented in a plasma enhanced chemical vapor deposition (PECVD) reactor. Such a reactor may take many different forms. Various embodiments are compatible with existing semiconductor processing equipment-in particular, PECVD reactors such as Sequel™ or Vector™ reactor chambers available from Lam Research Corporation. The various embodiments may be implemented on a multi-station or single station tool. In specific embodiments, the 300 mm Lam Vector™ tool having a 4-station deposition scheme or the 200 mm Sequel™ tool having a 6-station deposition scheme are used.

Generally, the apparatus will include one or more chambers or reactors that each include one or more stations. Chambers will house one or more wafers and are suitable for wafer processing. The one or more chambers maintain the wafer in a defined position or positions, by preventing rotation, vibration, or other agitation. In some embodiment, a wafer undergoing AHM deposition is transferred from one station to another within a chamber during the process. For example, a 2000 Å AHM deposition may occur entirely at one station, or 500 Å of film may be deposited at each of four stations in accordance with various embodiments. Alternatively, any other fraction of the total film thickness may be deposited at any number of stations. In various embodiments where more than one AHM is deposited, more than one station may be used to deposit each AHM layer. During processing, each wafer is held in place by a pedestal, wafer chuck, and/or other wafer holding apparatus. For certain operations where the wafer is to be heated, the apparatus may include a heater such as a heating plate.

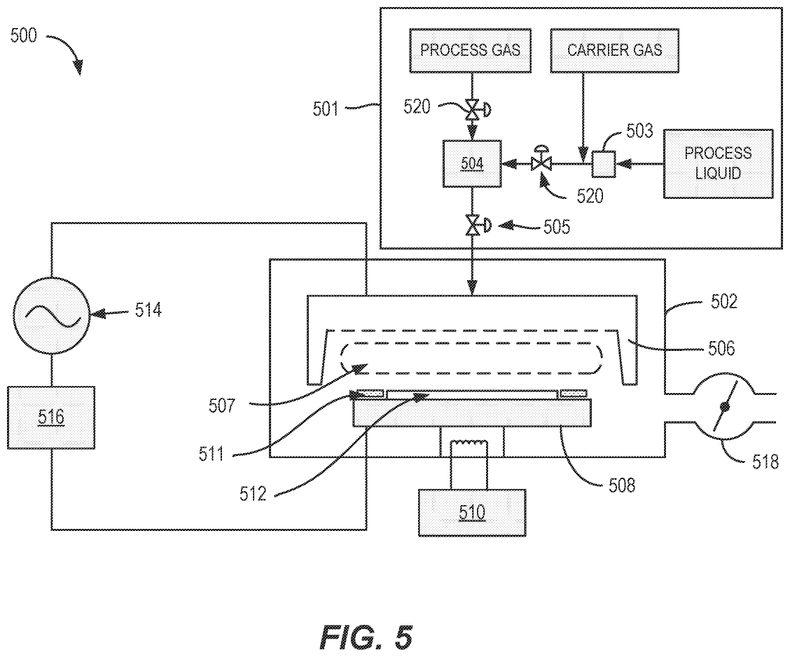

FIG. 5 schematically shows an embodiment of a process station 500 that may be used to deposit material using plasma enhanced chemical vapor deposition (PECVD). For simplicity, the process station 500 is depicted as a standalone process station having a process chamber body 502 for maintaining a low-pressure environment. However, it will be appreciated that a plurality of process stations 500 may be included in a common process tool environment. Further, it will be appreciated that, in some embodiments, one or more hardware parameters of process station 500, including those discussed in detail below, may be adjusted programmatically by one or more computer controllers.

Process station 500 fluidly communicates with reactant delivery system 501 for delivering process gases to a distribution showerhead 506. Reactant delivery system 501 includes a mixing vessel 504 for blending and/or conditioning process gases for delivery to showerhead 506. One or more mixing vessel inlet valves 520 may control introduction of process gases to mixing vessel 504. Similarly, a showerhead inlet valve 505 may control introduction of process gasses to the showerhead 506.

For example, the embodiment of FIG. 5 includes a vaporization point 503 for vaporizing liquid reactant to be supplied to mixing vessel 504. In some embodiments, vaporization point 503 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 503 may be heat traced. In some examples, mixing vessel 504 may also be heat traced. In one non-limiting example, piping downstream of vaporization point 503 has an increasing temperature profile extending from approximately 100 °C to approximately 150 °C at mixing vessel 504.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 503. In one scenario, a liquid injector may be mounted directly to mixing vessel 504. In another scenario, a liquid injector may be mounted directly to showerhead 506.

In some embodiments, a liquid flow controller upstream of vaporization point 503 may be provided for controlling a mass flow of liquid for vaporization and delivery to process station 500. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 506 distributes process gases toward substrate 512. In the embodiment shown in FIG. 5, substrate 512 is located beneath showerhead 506, and is shown resting on a pedestal 508. It will be appreciated that showerhead 506 may have any suitable shape, and may have any suitable number and arrangement of ports for distributing processes gases to substrate 512. A focus ring 511 is also shown resting on pedestal 508. Focus ring 511 may be any focus ring as described herein.

In some embodiments, a microvolume 507 is located beneath showerhead 506. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 508 may be raised or lowered to expose substrate 512 to microvolume 507 and/or to vary a volume of microvolume 507. For example, in a substrate transfer phase, pedestal 508 may be lowered to allow substrate 512 to be loaded onto pedestal 508. During a deposition process phase, pedestal 508 may be raised to position substrate 512 within microvolume 507. In some embodiments, microvolume 507 may completely enclose substrate 512 as well as a portion of pedestal 508 to create a region of high flow impedance during a deposition process.

Optionally, pedestal 508 may be lowered and/or raised during portions the deposition process to modulate process pressure, reactant concentration, etc., within microvolume 507. In one scenario where process chamber body 502 remains at a base pressure during the deposition process, lowering pedestal 508 may allow microvolume 507 to be evacuated. Example ratios of microvolume to process chamber volume include, but are not limited to, volume ratios between 1:700 and 1:10. It will be appreciated that, in some embodiments, pedestal height may be adjusted programmatically by a suitable computer controller.

In another scenario, adjusting a height of pedestal 508 may allow a plasma density to be varied during plasma activation and/or treatment cycles included in the deposition process. At the conclusion of the deposition process phase, pedestal 508 may be lowered during another substrate transfer phase to allow removal of substrate 512 from pedestal 508.

While the example microvolume variations described herein refer to a height-adjustable pedestal, it will be appreciated that, in some embodiments, a position of showerhead 506 may be adjusted relative to pedestal 508 to vary a volume of microvolume 507. Further, it will be appreciated that a vertical position of pedestal 508 and/or showerhead 506 may be varied by any suitable mechanism within the scope of the present disclosure. In some embodiments, pedestal 508 may include a rotational axis for rotating an orientation of substrate 512. It will be appreciated that, in some embodiments, one or more of these example adjustments may be performed programmatically by one or more suitable computer controllers.

Returning to the embodiment shown in FIG. 5, showerhead 506 and pedestal 508 electrically communicate with RF power supply 514 and matching network 516 for powering a plasma. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Examples of suitable powers are included above. Likewise, RF power supply 514 may provide RF power of any suitable frequency. In some embodiments, RF power supply 514 may be configured to control high-and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a hydrocarbon precursor gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some embodiments, pedestal 508 may be temperature controlled via heater 510. Further, in some embodiments, pressure control for deposition process station 500 may be provided by butterfly valve 518. As shown in the embodiment of FIG. 5, butterfly valve 518 throttles a vacuum provided by a downstream vacuum pump (not shown). However, in some embodiments, pressure control of process station 500 may also be adjusted by varying a flow rate of one or more gases introduced to process station 500.

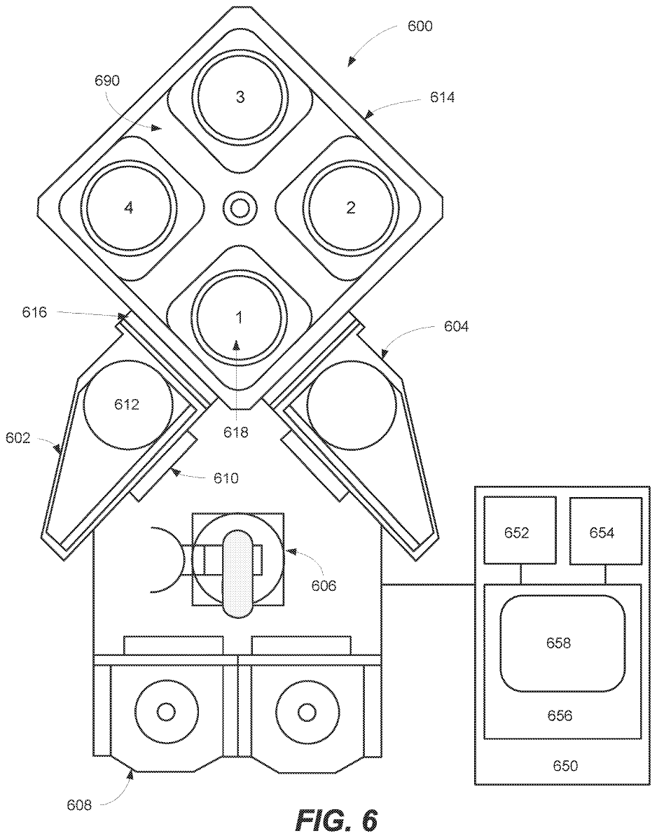

FIG. 6 shows a schematic view of an embodiment of a multi-station processing tool 600 with an inbound load lock 602 and an outbound load lock 604, either or both of which may comprise a remote plasma source. A robot 606, at atmospheric pressure, is configured to move wafers from a cassette loaded through a pod 608 into inbound load lock 602 via an atmospheric port 610. A wafer is placed by the robot 606 on a pedestal 612 in the inbound load lock 602, the atmospheric port 610 is closed, and the load lock is pumped down. Where the inbound load lock 602 comprises a remote plasma source, the wafer may be exposed to a remote plasma treatment in the load lock prior to being introduced into a processing chamber 614. Further, the wafer also may be heated in the inbound load lock 602 as well, for example, to remove moisture and adsorbed gases. Next, a chamber transport port 616 to processing chamber 614 is opened, and another robot (not shown) places the wafer into the reactor on a pedestal of a first station shown in the reactor for processing. While the embodiment depicted in FIG. 4 includes load locks, it will be appreciated that, in some embodiments, direct entry of a wafer into a process station may be provided.

The depicted processing chamber 614 comprises four process stations, numbered from 1 to 4 in the embodiment shown in FIG. 6. Each station has a heated pedestal (shown at 618 for station 1), and gas line inlets. It will be appreciated that in some embodiments, each process station may have different or multiple purposes. While the depicted processing chamber 614 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 6 also depicts an embodiment of a wafer handling system 690 for transferring wafers within processing chamber 614. In some embodiments, wafer handling system 690 may transfer wafers between various process stations and/or between a process station and a load lock. It will be appreciated that any suitable wafer handling system may be employed. Non-limiting examples include wafer carousels and wafer handling robots. FIG. 6 also depicts an embodiment of a system controller 650 employed to control process conditions and hardware states of process tool 600. System controller 650 may include one or more memory devices 656, one or more mass storage devices 654, and one or more processors 652. Processor 652 may include a CPU or computer, analog and/or digital input/output connections, stepper motor controller boards, etc.

In some embodiments, system controller 650 controls all of the activities of process tool 600. System controller 650 executes system control software 658 stored in mass storage device 654, loaded into memory device 656, and executed on processor 652. System control software 658 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 600. System control software 658 may be configured in any suitable way. For example, various process tool component subroutines or control objects may be written to control operation of the process tool components necessary to carry out various process tool processes in accordance with the disclosed methods. System control software 658 may be coded in any suitable computer readable programming language.

In some embodiments, system control software 658 may include input/output control (IOC) sequencing instructions for controlling the various parameters described above. Other computer software and/or programs stored on mass storage device 654 and/or memory device 656 associated with system controller 650 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 618 and to control the spacing between the substrate and other parts of process tool 600.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 650. The user interface may include a display screen, graphical software displays of the apparatus and/or process conditions, and user input devices such as pointing devices, keyboards, touch screens, microphones, etc.

In some embodiments, parameters adjusted by system controller 650 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 650 from various process tool sensors. The signals for controlling the process may be output on the analog and digital output connections of process tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, and/or the SPEED@ product family, each available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

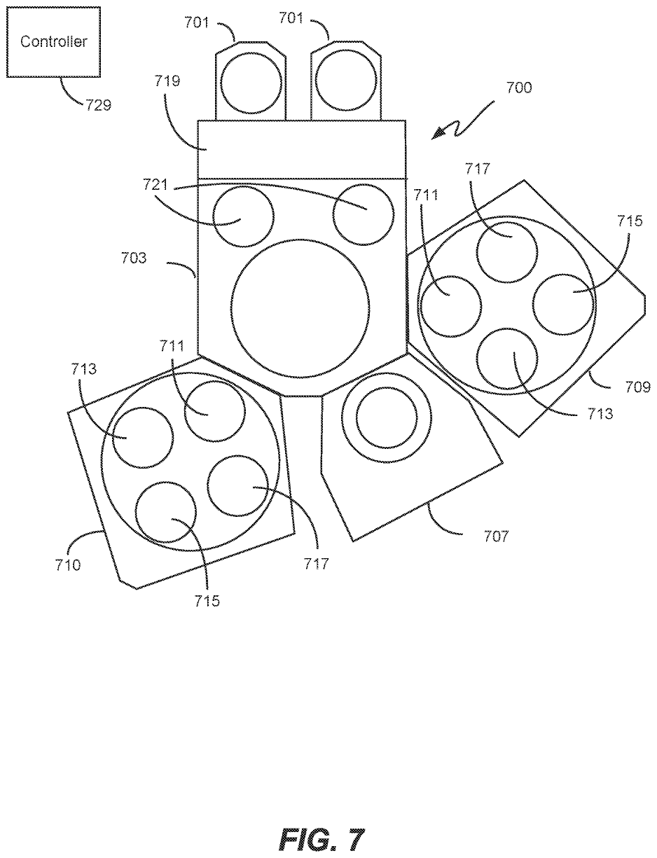

FIG. 7 is a block diagram of a processing system suitable for conducting thin film deposition processes in accordance with certain embodiments. The system 700 includes a transfer module 703. The transfer module 703 provides a clean, pressurized environment to minimize risk of contamination of substrates being processed as they are moved between various reactor modules. Mounted on the transfer module 703 are two multi-station reactors 709 and 710, each capable of performing atomic layer deposition (ALD) and/or chemical vapor deposition (CVD) according to certain embodiments. Reactors 709 and 710 may include multiple stations 711, 713, 715, and 717 that may sequentially or non-sequentially perform operations in accordance with disclosed embodiments. The stations may include a heated pedestal or substrate support, one or more gas inlets or showerhead or dispersion plate.

Also mounted on the transfer module 703 may be one or more single or multi-station modules 707 capable of performing plasma or chemical (non-plasma) pre-cleans, or any other processes described in relation to the disclosed methods. The module 707 may in some cases be used for various treatments to, for example, prepare a substrate for a deposition process. The module 707 may also be designed/configured to perform various other processes such as etching or polishing. The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all of the activities of the deposition apparatus. The system controller 729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 729 may be employed in some embodiments.

Typically there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 729. The signals for controlling the process are output on the analog and digital output connections of the deposition apparatus 700.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

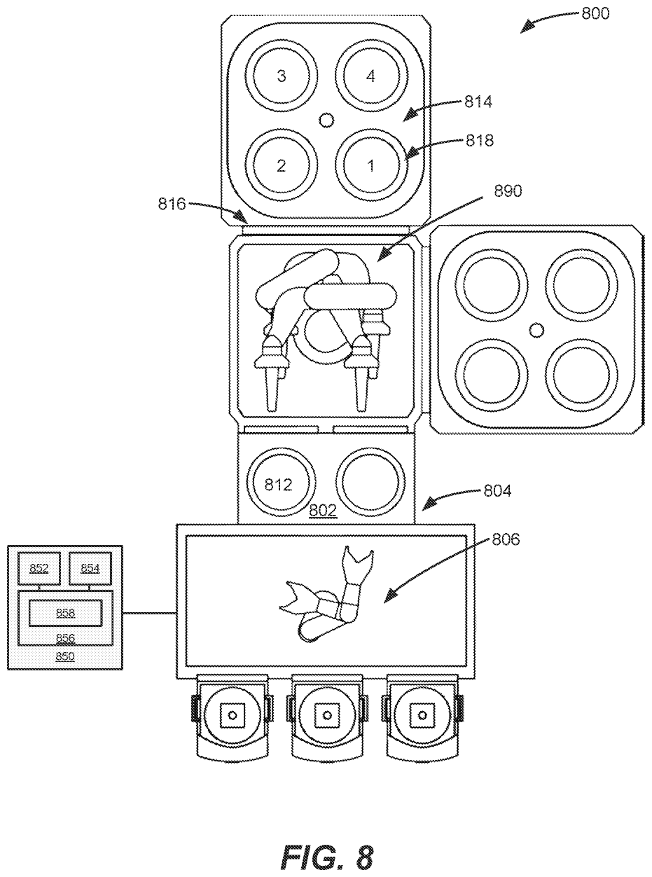

As described above, one or more process stations may be included in a multi-station processing tool. FIG. 8 shows a schematic view of an embodiment of a multi-station processing tool 800 with an inbound load lock 802 and an outbound load lock 804, either or both of which may comprise a remote plasma source. A robot 806, at atmospheric pressure, is configured to move substrates or wafers from a cassette loaded through a pod 808 into inbound load lock 802 via an atmospheric port 810. A substrate is placed by the robot 806 on a pedestal 812 in the inbound load lock 802, the atmospheric port 810 is closed, and the load lock is pumped down. Where the inbound load lock 802 comprises a remote plasma source, the substrate may be exposed to a remote plasma treatment in the load lock prior to being introduced into a processing chamber 814. Further, the substrate also may be heated in the inbound load lock 802 as well, for example, to remove moisture and adsorbed gases. Next, a chamber transport port 816 to processing chamber 814 is opened, and another robot (not shown) places the substrate into the reactor on a pedestal of a first station shown in the reactor for processing. While the embodiment depicted in FIG. 8 includes load locks, it will be appreciated that, in some embodiments, direct entry of a substrate into a process station may be provided. In various embodiments, the soak gas is introduced to the station when the substrate is placed by the robot 806 on the pedestal 812.

The depicted processing chamber 814 comprises four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. For example, in some embodiments, a process station may be switchable between an ALD and PEALD process mode. Additionally or alternatively, in some embodiments, processing chamber 814 may include one or more matched pairs of ALD and plasma-enhanced ALD process stations. While the depicted processing chamber 814 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 depicts an embodiment of a wafer handling system 890 for transferring substrates within processing chamber 814. In some embodiments, wafer handling system 890 may transfer substrates between various process stations and/or between a process station and a load lock. It will be appreciated that any suitable wafer handling system may be employed. Non-limiting examples include wafer carousels and wafer handling robots. FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog and/or digital input/output connections, stepper motor controller boards, etc. In some embodiments, system controller 850 includes machine-readable instructions for performing operations such as those described herein.

In some embodiments, system controller 850 controls the activities of process tool 800. System controller 850 executes system control software 858 stored in mass storage device 854, loaded into memory device 856, and executed on processor 852. Alternatively, the control logic may be hard coded in the system controller 850. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 858 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 800. System control software 858 may be configured in any suitable way. For example, various process tool component subroutines or control objects may be written to control operation of the process tool components used to carry out various process tool processes. System control software 858 may be coded in any suitable computer readable programming language.

In some implementations, a controller 850 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 850, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Conclusion

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A system, comprising:
a process chamber comprising a pedestal comprising a top surface;
a focus ring installed on the top surface of the pedestal, wherein the focus ring comprises an annular ring having an inner diameter and an outer diameter; and
a controller configured to execute machine-readable instructions to control the process chamber for:
depositing a carbon-containing film using a plasma-enhanced deposition process on a wafer.

2. The system of claim 1, wherein the focus ring comprises a dielectric material.

3. The system of claim 2, wherein the dielectric material is aluminum oxide.

4. The system of claim 1, wherein the inner diameter of the focus ring is between about 11.9 inches and about 13 inches.

5. The system of claim 1, wherein the outer diameter of the focus ring is at least about 14 inches.

6. The system of claim 1, wherein the focus ring comprises posts that contact the top surface of the pedestal.

7. The system of claim 6, wherein a gap between the annular ring and the top surface of the pedestal is at least about 0.01 inches.

8. The system of claim 6, wherein a distance between the top surface of the pedestal and a top surface of the focus ring when the focus ring is installed on the top surface of the pedestal is between about 0.06 and about 0.182 inches.

9. The system of claim 1, wherein the process chamber further comprises a showerhead, and a distance between the showerhead and the top surface of the pedestal is between about 0.5 inches and about 1.5 inches.

10. The system of claim 1, wherein depositing the carbon-containing film is performed at a temperature between about 200 °C and about 650 °C.

11. The system of claim 1, wherein depositing the carbon-containing film is performed at a temperature between about 250 °C and about 550 °C.

12. The system of claim 1, wherein depositing the carbon-containing film is performed at a temperature less than about 550 °C.

13. The system of claim 1, wherein depositing the carbon-containing film is performed at a low-frequency power between about 1000 W and about 1500 W per 300 mm wafer.

14. The system of claim 1, wherein depositing the carbon-containing film is performed at a high-frequency power between about 100 W and about 250 W per 300 mm wafer.

15. The system of claim 1, wherein a non-uniformity of the carbon-containing film at a radius greater than about 130 mm is less than about 10%.

16. A method, comprising:
receiving a wafer in a process chamber comprising a pedestal comprising a top surface, wherein a focus ring is installed on the top surface of the pedestal, wherein the focus ring comprises an annular ring having an inner diameter and an outer diameter; and
depositing a carbon-containing film using a plasma-enhanced deposition process on the wafer.

17. The method of claim 16, wherein the focus ring comprises a dielectric material.

18. The method of claim 17, wherein the dielectric material is aluminum oxide.

19. The method of claim 16, wherein the inner diameter of the focus ring is between about 11.9 inches and about 13 inches.

20. The method of claim 16, wherein the outer diameter of the focus ring is at least about 14 inches.

21-30. (canceled)
